(19) United States
(12) Patent Application Publication
(10) Pub. No.: US 2013/0143334 A1
(43) Pub. Date: Jun. 6, 2013

(54) METHOD OF ENHANCING COLOR RENDERING INDEX OF A WHITE LED

(71) Applicants: WEI-YUAN CHENG, TAIPEI CITY (TW); CHIUNG-CHIEH LIEN, TAIPEI CITY (TW)

(72) Inventors: WEI-YUAN CHENG, TAIPEI CITY (TW); CHIUNG-CHIEH LIEN, TAIPEI CITY (TW)

(73) Assignee: HUNG TA TRADING CO., LTD., Taipei City (TW)

(21) Appl. No.: 13/367,144

(22) Filed: Feb. 6, 2012

Related U.S. Application Data
(60) Provisional application No. 61/565,738, filed on Dec. 1, 2011.

(30) Foreign Application Priority Data
Dec. 15, 2011 (TW) 100146647

(51) Int. Cl. H01L 33/50; H01L 33/48

(52) U.S. Cl. 438/15; 438/27; 257/E33.061

(57) ABSTRACT

The present invention discloses a method of enhancing color rendering index (CRI) of a white light emitting diode (LED), and particularly discloses a method of enhancing CRI of a white LED by adding a blue-green (or aquamarine) phosphor which can emit a light having wavelength of 485 nm to 519 nm.

### CROSS-REFERENCE TO RELATED APPLICATIONS

The entire contents of U.S. Provisional Application No. 61/565,738 (Att. Docket HU8630PR), filed on Dec. 1, 2011, and Taiwan Patent Application No. 100146647, filed on Dec. 15, 2011, from which this application claims priority, are incorporated herein by reference.

### BACKGROUND OF THE INVENTION

1. Field of the Invention

The present invention relates to a method of enhancing color rendering index of a white light emitting diode (LED), and particularly relates to a method of enhancing color rendering index of a white LED by adding a blue-green (or aquamarine) phosphor which can emit a light having wavelength of 485 nm to 519 nm.

2. Description of Related Art

Currently, light emitting diode (LED) is used instead of tungsten lamp and fluorescent lamp as a new lighting tool to be applied in various fields gradually, for example LCD display, streetlight, road sign, etc. Generally, the white LED which simulates the sunlight is used in most fields.

Now, most of the white LEDs are manufactured by packaging a blue LED with different phosphors. A common technique of manufacturing the white LED is to coat a layer of yellow phosphor, for example yellow YAG phosphor, yellow TAG phosphor, etc., on a blue LED. The blue light emitted from the blue LED excites the yellow phosphor to emit yellow light, and the yellow light is mixed with the blue light emitted from the blue LED for forming white light. The white light is formed by the complementation of the blue light and the yellow light.

FIG. 1 illustrates the spectrogram of a white LED manufacturing by a blue LED and a yellow phosphor (YAG), and Table 1 shows the test result of luminance and color rendering index (CRI) of the white LED.

TABLE 1
Blue LED chip + yellow phosphor(YAG)

| TEST | luminance (LOP) (Im) | color rendering index (CRI) (Ra) |
|---|---|---|
| 1 | 6.182 | 74.853 |
| 2 | 6.121 | 75.554 |
| 3 | 6.112 | 75.96 |
| 4 | 6.15 | 75.391 |
| 5 | 6.167 | 75.06 |
| 6 | 6.155 | 75.525 |
| 7 | 6.141 | 75.289 |
| 8 | 6.138 | 74.358 |
| 9 | 6.158 | 74.94 |
| 10 | 6.094 | 75.523 |
| 11 | 6.102 | 75.445 |
| 12 | 6.192 | 75.845 |
| 13 | 6.172 | 75.071 |
| 14 | 6.165 | 75.917 |
| 15 | 6.214 | 76.154 |
| 16 | 6.182 | 74.762 |
| 17 | 6.114 | 74.948 |
| 18 | 6.15 | 15.853 |
| AVG. | 6.1505 | 75.3582 |

By FIG. 1 and Table 1, it is known that the average luminance (or brightness) of the white LED manufacturing by the blue LED and the yellow phosphor (YAG) is about 6.1501 lm, and the average CRI of the white LED is about 75.3582, and most test results of CRI of the white LED are in the range of 70-75.

Therefore, the CRI of the white LED manufacturing by this technique cannot meet the requirement that the CRI of the white LED need to be greater than 80. Accordingly, a white LED manufacturing by adding red phosphor into the white LED manufacturing by the blue LED and the yellow phosphor (YAG) is developed for meeting the requirement of high CRI (>80). However, although the CRI of the white LED can be increased by adding the red phosphor into the white LED, it is increased a little. Therefore, there is a need to add many red phosphor into the white LED for reaching high CRI (>80). This technique has two disadvantages: (1) the color of the light emitted from the white LED is changed by adding many red phosphor into the white LED and the white LED cannot emit white light and therefore there is a need to add a green phosphor to correct the color of the light emitted from the white LED and the white LED can emit white light again; and (2) the CRI of the white LED can be increased by adding the red phosphor and the green phosphor but the highest CRI of the white LED which can be obtained by this technique is about 80. Although the CRI of the white LED is increased by adding the red phosphor and the green phosphor, the luminance (or brightness) of the white LED is decreased significantly.

Nowadays, another common technique of manufacturing the white LED is developed. This technique is to add a red phosphor and a green phosphor on a blue LED to manufacture a white LED. The blue light emitted from the blue LED excites the red phosphor and the green phosphor to emit red light and green light respectively, and the red light and the green light are mixed with the blue light emitted from the blue LED for forming white light. FIG. 2 illustrates the spectrogram of a white LED manufacturing by a blue LED, a red phosphor and a green phosphor, and Table 2 shows the test result of luminance and CRI of the white LED.

TABLE 2
Blue LED chip + red phosphor + green phosphor

| TEST | luminance (LOP) (Im) | color rendering index (CRI) (Ra) |
|---|---|---|
| 1 | 4.751 | 78.55 |
| 2 | 4.797 | 76.582 |
| 3 | 4.833 | 77.481 |
| 4 | 4.838 | 78.573 |
| 5 | 4.962 | 77.045 |
| 6 | 4.94 | 77.115 |
| 7 | 4.632 | 76.508 |
| 8 | 4.897 | 76.053 |
| 9 | 4.775 | 75.746 |
| 10 | 4.547 | 88.792 |
| 11 | 4.867 | 79.024 |
| 12 | 5.059 | 76.58 |
| 13 | 4.78 | 77.77 |
| 14 | 4.982 | 76.925 |
| 15 | 4.777 | 77.644 |
| 16 | 4.862 | 80.12 |
| 17 | 4.967 | 76.888 |
| 18 | 4.867 | 77.572 |
| 19 | 4.821 | 77.778 |
| 20 | 4.821 | 80.292 |
| 21 | 4.969 | 78.763 |
| AVG. | 4.844952 | 78.181 |

By FIG. 2 and Table 2, it is known that the average luminance (or brightness) of the white LED manufacturing by the a blue LED, the red phosphor and the green phosphor is about 4.844952 lm, and the average CRI of the white LED is about 78.181, and most test results of CRI of the white LED are in the range of 75-79. Therefore, the CRI of the white LED manufacturing by this technique cannot meet the requirement of high CRI (>80) but the luminance (or brightness) of the white LED manufacturing by this technique is significantly decreased.

Therefore, there is a need for a method of enhancing CRI of a white LED. By this method, the CRI of the white LED is significantly increased but the light emitted from the white LED and the color of the light will not be changed and influenced and the luminance (or brightness) of the white LED will not be significantly decreased.

### SUMMARY OF THE INVENTION

In view of the foregoing, one object of the present invention is to provide a method of enhancing color rendering index (CRI) of a white light emitting diode (LED). By this method, the CRI of the white LED is significantly increased but the light emitted from the white LED and the color of the light will not be changed and influenced and the luminance (or brightness) of the white LED will not be significantly decreased.

Another object of the present invention is to provide a method of enhancing CRI of a white LED. It can be performed in any conventional package process of a white LED. In this method, a simple technique which will not significantly change the original steps of the conventional package process is applied to enhance CRI of the white light but the white LED can maintain the luminance (or brightness) of the white LED.

According to the objects above, a method of enhancing CRI of a white LED is disclosed herein. The method comprises following steps: providing an LED chip to be packaged for forming a white LED and adding a blue-green phosphor body in the package process of the white LED wherein the blue-green phosphor body absorbs a portion of light emitted from said LED chip and the blue-green phosphor body is excited to emit blue-green light by the absorbed light. The blue-green light is mixed with the light emitted from the LED chip to enhance color rendering index of the white LED. The blue-green (or aquamarine) phosphor body is a blue-green (or aquamarine) phosphor which can emit a light having wavelength of 485 nm to 519 nm.

Therefore, the present invention provides a method of enhancing CRI of a white LED. By this method, the CRI of the white LED is significantly increased but the light emitted from the white LED and the color of the light will not be changed and influenced and the luminance (or brightness) of the white LED will not be significantly decreased.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates the spectrogram of a conventional white LED manufacturing by a blue LED and a yellow phosphor.

FIG. 2 illustrates the spectrogram of a conventional white LED manufacturing by a blue LED, a red phosphor and a green phosphor.

FIG. 3 is a flow chart illustrating a method of enhancing color rendering index (CRI) of a white LED in accordance with one embodiment of this invention.

FIG. 4 illustrates the spectrogram of a white LED in accordance with one embodiment of this invention.

FIG. 5 illustrates the spectrogram of a white LED in accordance with another embodiment of this invention.

FIG. 6 illustrates the spectrogram of a white LED in accordance with still another embodiment of this invention.

### DETAILED DESCRIPTION OF THE PREFERRED EMBODIMENT

The detailed description of the present invention will be discussed in the following embodiments, which are not intended to limit the scope of the present invention, and can be adapted for other applications. While drawings are illustrated in detail, it is appreciated that the quantity of the disclosed components may be greater or less than that disclosed, except where expressly restricting the amount of the components. Although specific embodiments have been illustrated and described, it will be appreciated by those skilled in the art that various modifications may be made without departing from the scope of the present invention, which is intended to be limited solely by the appended claims.

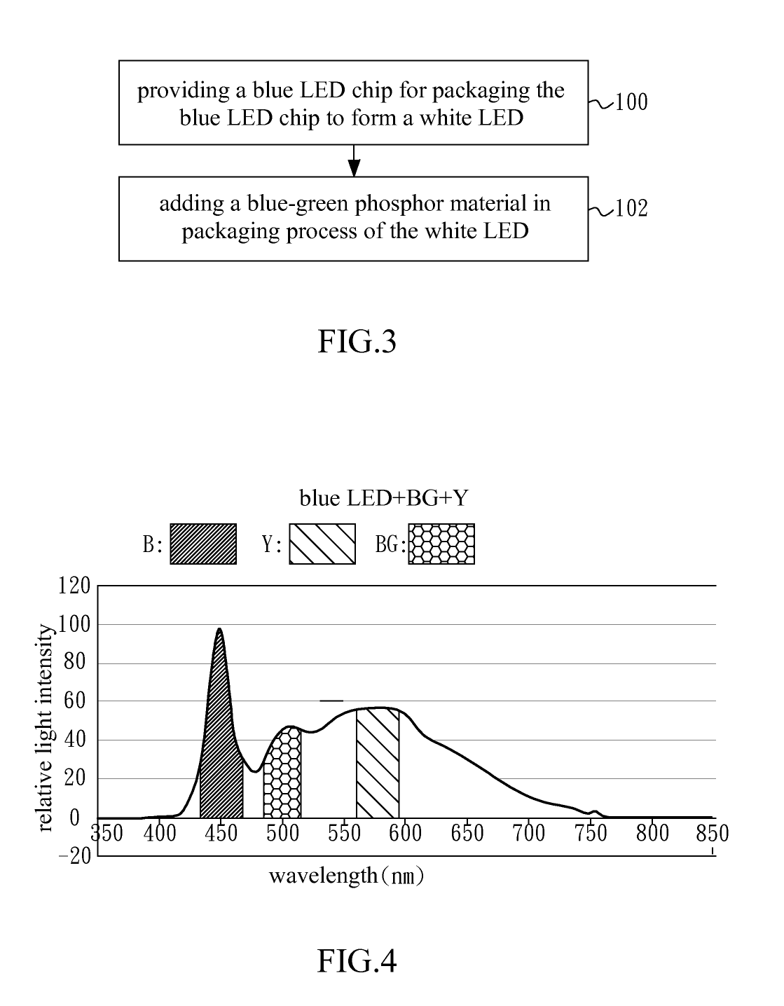

FIG. 3 is a flow chart illustrating a method of enhancing color rendering index (CRI) of a white LED in accordance with one embodiment of this invention. First, an LED chip is provided and LED chip is packaged to form a white LED (step 100). The LED chip is a blue LED chip but not limited to this. According to designs and requirements of the package process of the white LED and the structure of the white LED, other LEDs, for example a purple LED, can be applied to form the white LED. The package process for the LED chip comprises following steps: die attaching wherein the LED chip is attached on a substrate by a die attached glue; baking the die attached glue to cure the die attached glue for fixing the LED chip on the substrate; wire bonding for electrically connecting electrodes of the LED chip with pins of the substrate; dispensing for adding phosphor glue to form a white LED; dispensing for adding phosphor glue to form a white LED; baking molding material to cure said molding material; and testing the white LED for confirming quality of said white LED. However, the package process for the LED chip applied in this invention is not limited in the above-mentioned steps of the package process and the steps of the package process can be increased, decreased, or changed according to designs and requirements of the package process of the white LED and the structure of the white LED.

After, a blue-green (or aquamarine) phosphor body is added on the LED chip in (or during) the package process for the LED chip (or the package process of the white LED) (step 102). The blue-green phosphor body absorbs a portion of light emitted from the LED chip and light emitted from the LED chip excites blue-green phosphor body to emit blue-green light having wavelength of 485 nm to 519 nm. The blue-green light is mixed with the light emitted from the LED chip to enhance color rendering index of the white LED. The blue-green phosphor body is a blue-green phosphor or a material comprising a blue-green phosphor, which can be excited by the light emitted from the LED chip to emit blue-green light having wavelength of 485 nm to 519 nm. The blue-green phosphor body comprises at least one following phosphor (or phoephor material): LuAG:(Lu,Y)3Al5O12:Ce, Ga-YAG:Y3(Al,Ga)5O12:Ce, TAG:Tb3Al5O12:Ce, (Ba,Sr,Ca)2SiO4, Sr3SiO5, CaAlSiN3, (Sr,Ca,Ba,Eu)2Si5N8-x-yOxCy, green SrSi2(O,Cl)2N2, and yellow (Ba,Sr)Si2(O,Cl)2N2. Generally, the blue-green phosphor body is added in the step of dispensing in the package process, but not limited to this. According to designs and requirements of the package process of the white LED, the blue-green phosphor body can be added in other step of the package process. The amount of the blue-green phosphor body added in the package process of the white LED is about 0.01 g. When the blue-green phosphor body is added in the step of dispensing in the package process, the amount of the blue-green phosphor body added in the package process of the white LED is about 0.25% weight percentage of the phosphor glue, but it can be changed according to designs and requirements of the package process of the white LED and the structure of the white LED.

The above-mentioned method of enhancing CRI of a white LED of this invention can be applied to various white LEDs manufactured by different techniques. For example, in the (package) process of the white LED manufactured by a blue LED and a yellow phosphor material, a yellow phosphor material need to be added in the (package) process except adding a blue-green phosphor body to perform the method of enhancing CRI of the white LED of this invention. The yellow phosphor material is a yellow phosphor which be excited to emit yellow light by the blue light emitted from the blue LED, for example yellow YAG phosphor, yellow TAG phosphor, yellow SILICATE phosphor, yellow Nitride phosphor, yellow nitrogen oxide phosphor, and other yellow phosphor. The yellow light is mixed with the blue light emitted from the blue LED for forming white light. The white light is formed by the complementation of the blue light and the yellow light. FIG. 4 illustrates the spectrogram of a white LED manufacturing by a blue LED, a yellow phosphor (YAG) and a blue-green phosphor (body), and Table 3 shows the test result of luminance and CRI of this white LED.

TABLE 3
Blue LED chip + yellow phosphor(YAG) + blue-green
phosphor

| TEST | luminance (LOP) (Im) | color rendering index (CRI) (Ra) |
|---|---|---|
| 1 | 5.995 | 85.359 |
| 2 | 5.934 | 85.53 |
| 3 | 6.029 | 86.007 |
| 4 | 5.876 | 85.422 |
| 5 | 5.939 | 87.075 |
| 6 | 6.009 | 85.664 |
| 7 | 5.89 | 86.993 |
| 8 | 5.779 | 87.043 |
| 9 | 5.851 | 85.66 |
| 10 | 5.941 | 87.368 |
| 11 | 5.903 | 85.991 |
| 12 | 5.939 | 86.235 |
| 13 | 5.941 | 86.232 |
| 14 | 5.917 | 86.382 |
| 15 | 5.994 | 86.63 |
| 16 | 6.022 | 86.385 |
| 17 | 5.934 | 86.992 |
| 18 | 5.92 | 86.123 |
| 19 | 5.91 | 87.001 |
| 20 | 5.834 | 84.51 |
| AVG. | 5.9254 | 86.2301 |

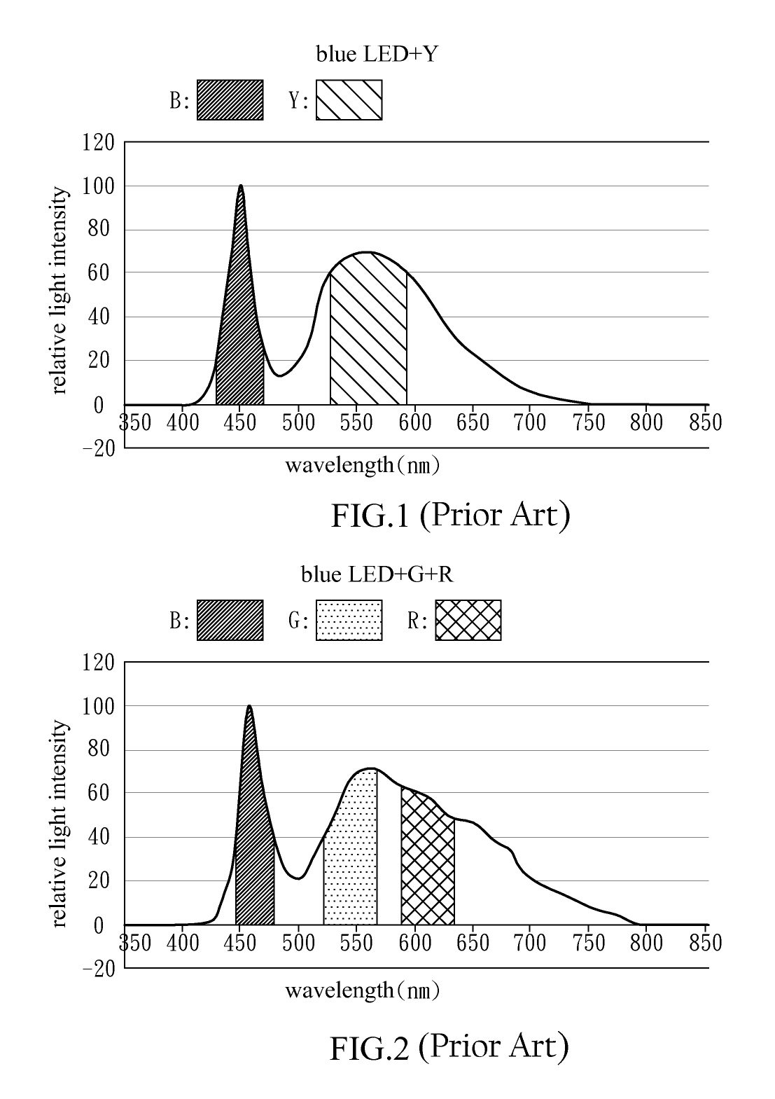

By FIG. 4 and Table 3, it is known that the average luminance (or brightness) of the white LED manufacturing by the blue LED, the yellow phosphor (YAG) and the blue-green phosphor (body) is about 5.9254 lm, and the average CRI of the white LED is about 86.2301, and most test results of CRI of the white LED are in the range of 84-87. Comparing with the conventional white LED manufactured by the blue LED and the yellow phosphor (referring to FIG. 1 and Table 1), the spectrogram of the white LED of this invention in range of 485 nm-519 nm is indeed enhanced and increased because of addition of the blue-green phosphor (body). Therefore, it proves that the CRI of the conventional white LED can be significantly increased by the method of enhancing CRI of a white LED of this invention and the CRI of the white LED can meet the requirement of high CRI (>80) by this method. Furthermore, by Table 3, it is known that the average luminance (or brightness) of the white LED manufacturing by the blue LED, the yellow phosphor (YAG) and the blue-green phosphor (body) is about 5.9254 lm. Comparing with the conventional white LED manufactured by the blue LED and the yellow phosphor (referring to FIG. 1 and Table 1), the average luminance (or brightness) of the conventional white LED is about 6.1505 and the difference between the average luminance (or brightness) of the conventional white LED and the average luminance (or brightness) of the white LED enhanced by the method of this invention is 0.2251 lm. It means that the average luminance (or brightness) of the white LED enhanced by the method of this invention is just decreased 0.2251 lm and it does not influence the luminance (or brightness) of the white LED significantly. However, comparing with the conventional method of enhancing CRI of the white LED, for example adding red phosphor, unlike the conventional method, the method of enhancing color rendering index of a white LED of this invention will not influence the luminance (or brightness) of the white LED significantly, but the color rendering index of the white LED can be increased about 14.42%. Therefore, the enhancing method of this invention is better than the conventional enhancing method, and the color rendering index of the white LED can be increased significantly without significant decreasing of the luminance (or brightness) of the white LED. The requirement of high CRI (>80) of the white LED can be achieved by the enhancing method of this invention.

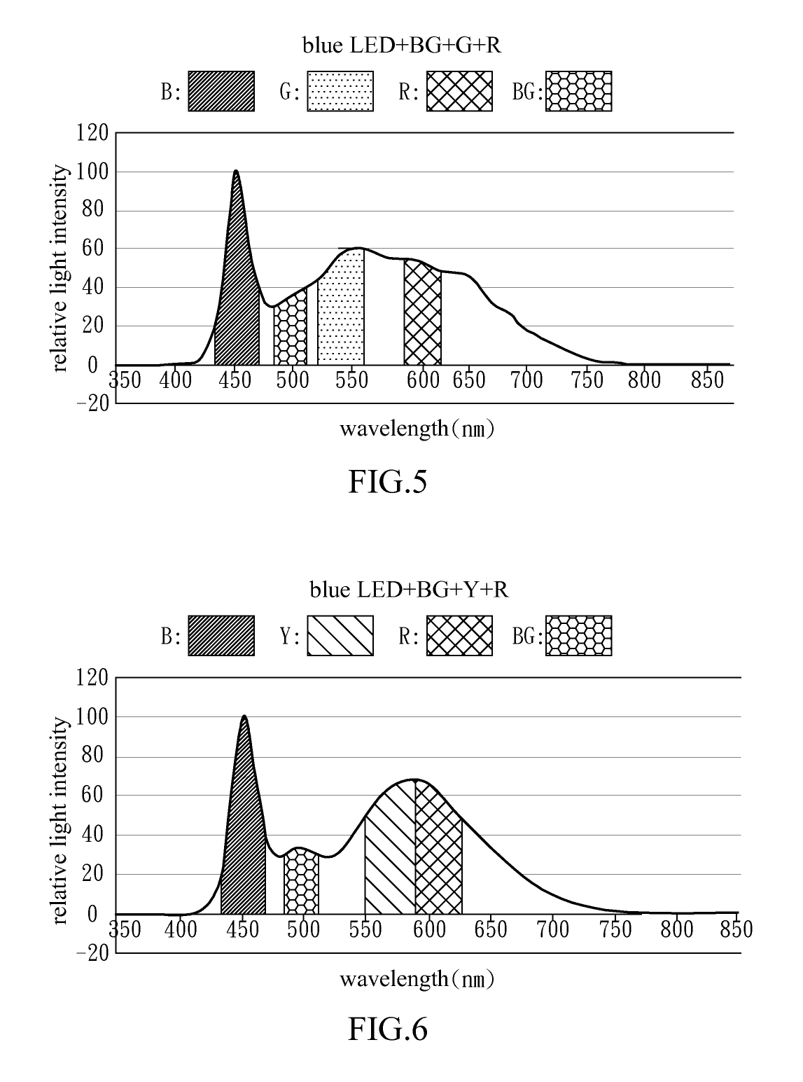

In another embodiment of this invention, in the (package) process of the white LED manufactured by a blue LED, a red phosphor material, and a green phosphor material, a blue-green phosphor body is added in the (package) process for enhancing the CRI of the white LED as the method of enhancing CRI of the white LED disclosed in this invention. The red phosphor material is a red phosphor which be excited to emit red light by the blue light emitted from the blue LED, for example red SILICATE phosphor, red Nitride phosphor, red nitrogen oxide phosphor, and other red phosphor. The green phosphor material is a green phosphor which be excited to emit green light by the blue light emitted from the blue LED, for example green SILICATE phosphor, green Nitride phosphor, green nitrogen oxide phosphor, and other green phosphor. The red light and the green light are mixed with the blue light emitted from the blue LED for forming white light. FIG. 5 illustrates the spectrogram of a white LED manufacturing by a red phosphor material, and a green phosphor material, and a blue-green phosphor (body), and Table 4 shows the test result of luminance and CRI of this white LED.

TABLE 4
Blue LED chip + red phosphor + green phosphor + blue-green
phosphor

| TEST | luminance (LOP) (Im) | color rendering index (CRI) (Ra) |
|---|---|---|
| 1 | 4.52 | 88.825 |
| 2 | 4.452 | 88.025 |
| 3 | 4.697 | 86.462 |
| 4 | 4.544 | 89.05 |
| 5 | 4.612 | 88.912 |
| 6 | 4.588 | 87.957 |
| 7 | 4.707 | 85.613 |
| 8 | 4.481 | 89.289 |
| 9 | 4.554 | 89.917 |
| 10 | 4.656 | 87.546 |
| 11 | 4.673 | 88.678 |
| 12 | 4.498 | 88.883 |
| 13 | 4.7 | 87.496 |
| 14 | 4.384 | 89.851 |
| 15 | 4.551 | 90.241 |
| 16 | 4.605 | 87.774 |
| 17 | 4.462 | 88.261 |
| 18 | 4.646 | 88.136 |
| 19 | 4.743 | 87.321 |
| 20 | 4.641 | 85.919 |
| 21 | 4.534 | 91.247 |
| 22 | 4.413 | 91.594 |
| 23 | 4.513 | 90.715 |
| 24 | 4.598 | 88.629 |
| 25 | 4.691 | 90.897 |
| 26 | 4.644 | 88.628 |
| 27 | 4.646 | 90.058 |
| 28 | 4.656 | 92.683 |
| 29 | 4.751 | 91.103 |
| 30 | 4.595 | 89.784 |
| 31 | 4.68 | 91.113 |
| 32 | 4.491 | 90.88 |
| 33 | 4.52 | 90.879 |
| 34 | 4.542 | 92.018 |
| 35 | 4.612 | 89.161 |
| 36 | 4.646 | 91.468 |
| 37 | 4.588 | 88.672 |
| 38 | 4.605 | 92.631 |
| 39 | 4.646 | 90.936 |
| 40 | 4.554 | 91.285 |
| 41 | 4.568 | 88.439 |
| 42 | 4.671 | 87.095 |
| 43 | 4.671 | 90.83 |
| AVG. | 4.596395 | 89.4163 |

By FIG. 5 and Table 4, it is known that the average luminance (or brightness) of the white LED manufacturing by the blue LED, the red phosphor (material), the green phosphor (material), and the blue-green phosphor (body) is about 4.59395 lm, and the average CRI of the white LED is about 89.4163, and most test results of CRI of the white LED are in the range of 87-91. Comparing with the conventional white LED manufactured by the blue LED, the red phosphor, and the green phosphor (referring to FIG. 2 and Table 2), the spectrogram of the white LED of this invention in range of 485 nm-519 nm is indeed enhanced and increased because of addition of the blue-green phosphor (body), and the color rendering index of the white LED can be increased about 14.37%. Therefore, it proves that the CRI of the conventional white LED can be significantly increased by the method of enhancing CRI of a white LED of this invention and the CRI of the white LED can meet the requirement of high CRI (>80) by this method. In addition, the CRI of the white LED enhanced by this enhancing method of this invention is almost 90, and it is a very high CRI which no conventional white LED has such high CRI before. Furthermore, by Table 4, it is known that the average luminance (or brightness) of the white LED manufacturing by the blue LED, the red phosphor (material), the green phosphor (material), and the blue-green phosphor (body) is about 4.59395 lm. Comparing with the conventional white LED manufactured by the blue LED, the red phosphor, and the green phosphor (referring to FIG. 2 and Table 2), the average luminance (or brightness) of the conventional white LED is about 4.844952 and the difference between the average luminance (or brightness) of the conventional white LED and the average luminance (or brightness) of the white LED enhanced by the method of this invention is 0.248557 lm. It means that the average luminance (or brightness) of the white LED enhanced by the method of this invention is just decreased 0.248557 lm and it does not influence the luminance (or brightness) of the white LED significantly. However, the color rendering index of the white LED can be increased about 14.37%. Therefore, the enhancing method of this invention is better than the conventional enhancing method, and the color rendering index of the white LED can be increased significantly without significant decreasing of the luminance (or brightness) of the white LED. The requirement of high CRI (>80) of the white LED can be achieved by the enhancing method of this invention. Furthermore, by the enhancing method of this invention, the CRI of the white LED can be much greater than the high CRI which is defined as CRI=80.

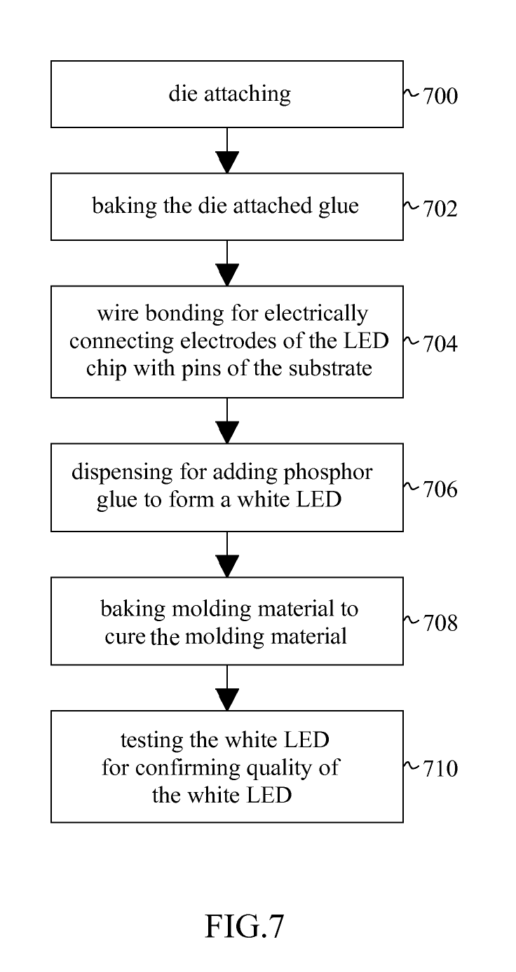

In still another embodiment of this invention, in the (package) process of the white LED manufactured by a blue LED, a yellow phosphor material, and a red phosphor material wherein the yellow phosphor material is added to form white light and the red phosphor material is added to correct the CRI of the white LED, a blue-green phosphor body is added in the (package) process for enhancing the CRI of the white LED as the method of enhancing CRI of the white LED disclosed in this invention. The yellow phosphor material is a yellow phosphor which be excited to emit yellow light by the blue light emitted from the blue LED, for example yellow YAG phosphor, yellow TAG phosphor, yellow SILICATE phosphor, yellow Nitride phosphor, yellow nitrogen oxide phosphor, and other yellow phosphor. The red phosphor material is a red phosphor which be excited to emit red light by the blue light emitted from the blue LED, for example red SILICATE phosphor, red Nitride phosphor, red nitrogen oxide phosphor, and other red phosphor. FIG. 6 illustrates the spectrogram of a white LED manufacturing by a yellow phosphor material, and a red phosphor material, and a blue-green phosphor (body). Similarly, the spectrogram of the white LED of this invention in range of 485 nm-519 nm is indeed enhanced and increased because of addition of the blue-green phosphor (body). Therefore, it proves that the CRI of the conventional white LED can be significantly increased by the method of enhancing CRI of a white LED of this invention.

According to above-mentioned embodiments, test data, drawings and tables, a method of enhancing color rendering index of a white LED is provided in this invention. In this method, a blue-green phosphor (body), which is excited to emit blue-green light having wavelength of 485 nm-519 nm by the light emitted from the LED chip, is added on the LED chip in (or during) the (package) process of the white LED. It means that the color rendering index of the white LED can be significantly increased (at least 14%) without significant changes of the original steps of the conventional package process and significant decreasing of the luminance (or brightness) of the white LED by this method. Therefore, the white LED can achieve the requirement of high CRI (>80) and the white LED can maintain the luminance (or brightness) of the white LED by this method. However, unlike the conventional enhancing method which a red phosphor is added to the correct color rendering index of the white LED, the color of the light emitted from the white LED enhanced by the method of this invention will not be influenced by this method.

1. A method of enhancing color rendering index of a white light emitting diode (LED), comprising:
providing an LED chip to be packaged for forming a white LED; and
adding a blue-green phosphor body during the package process of the white LED wherein said blue-green phosphor body absorbs a portion of light emitted from said LED chip and said blue-green phosphor body is excited to emit blue-green light by the absorbed light and the blue-green light is mixed with the light emitted from said LED chip to enhance color rendering index of the white LED, and said blue-green light emitted from said blue-green phosphor body has wavelength of 485 nm-519 nm and said blue-green phosphor body comprises at least one following phosphor material: LuAG:(Lu,Y)3Al5O12:Ce, Ga-YAG:Y3(Al,Ga)5O12:Ce, TAG:Tb3Al5O12:Ce, (Ba,Sr,Ca)2SiO4, Sr3SiO5, CaAlSiN3, (Sr,Ca,Ba,Eu)2Si5N8-x-yOxCy, green SrSi2(O,Cl)2N2, and yellow (Ba,Sr)Si2(O,Cl)2N2.

2. The method of claim 1, wherein the package process of the white LED comprises:
die attaching wherein said LED chip is attached on a substrate by a die attached glue;
baking said die attached glue to cure said die attached glue for fixing said LED chip on said substrate;
wire bonding for electrically connecting electrodes of said LED chip with pins of said substrate;
dispensing for adding phosphor glue to form a white LED;
baking molding material to cure said molding material; and
testing the white LED for confirming quality of said white LED.

3. The method of claim 1, wherein said LED chip is a blue LED chip.

4. The method of claim 2, wherein said blue-green phosphor body is added in said step of dispensing.

5. (canceled)

6. (canceled)

7. The method of claim 1, wherein amount of said blue-green phosphor body added in the package process of the white LED is about 0.01 g.

8. The method of claim 2, wherein amount of said blue-green phosphor body added in the package process of the white LED is about 0.25% weight percentage of said phosphor glue.

9. The method of claim 1, further comprising adding a yellow phosphor body in the package process of the white LED wherein said yellow phosphor body is excited by the light emitted from said LED chip to emit yellow light.

10. The method of claim 9, wherein said yellow phosphor body is a yellow phosphor.

11. The method of claim 9, further comprising adding a red phosphor body in the package process of the white LED wherein said red phosphor body is excited by the light emitted from said LED chip to emit red light.

12. The method of claim 11, wherein said red phosphor body is a red phosphor.

13. The method of claim 1, comprising adding a green phosphor body in the package process of the white LED wherein said green phosphor body is excited by the light emitted from said LED chip to emit green light.

14. The method of claim 13, wherein said green phosphor body is a green phosphor.

15. The method of claim 14, further comprising adding a red phosphor body in the package process of the white LED wherein said red phosphor body is excited by the light emitted from said LED chip to emit red light.

16. The method of claim 15, wherein said red phosphor body is a red phosphor.
